(19) United States
(12) Patent Application Publication
(10) Pub. No.: US 2025/0151280 A1
(43) Pub. Date: May 8, 2025

(54) SEMICONDUCTOR DEVICE

(71) Applicant: Samsung Electronics Co., Ltd., Suwon-si (KR)

(72) Inventors: Suseong NOH, Suwon-si (KR); Kwangsoo KIM, Suwon-si (KR); Taeyoung KIM, Suwon-si (KR); Ilho MYEONG, Suwon-si (KR); Sanghyun PARK, Suwon-si (KR); Suhwan LIM, Suwon-si (KR)

(73) Assignee: Samsung Electronics Co., Ltd., Suwon-si (KR)

(21) Appl. No.: 18/918,694

(22) Filed: Oct. 17, 2024

(30) Foreign Application Priority Data
Nov. 7, 2023 (KR) 10-2023-0153100

(51) Int. Cl. H10B 43/40; G11C 16/04; H01L 25/065; H10B 41/10; H10B 41/27; H10B 41/35; H10B 41/41; H10B 43/10; H10B 43/27; H10B 43/35; H10B 80/00

(52) U.S. Cl. CPC H10B 43/40; G11C 16/0483; H01L 25/0657; H10B 41/10; H10B 41/27; H10B 41/35; H10B 41/41; H10B 43/10; H10B 43/27; H10B 43/35; H10B 80/00; H01L 2225/06506

(57) ABSTRACT

A semiconductor device including a peripheral circuit structure, a cell structure including gate electrodes and stacked on the peripheral circuit structure, the cell structure including a cell region, a connection region, and a peripheral circuit connection region, the cell structure, a plurality of channel structures extending in a vertical direction through the gate electrodes in the cell region, each of the plurality of channel structures including a first end portion close to the peripheral circuit structure and a second end portion opposite to the first end portion, and a common source layer connected to the second end portion of each of the channel structures in the cell region may be provided.

### CROSS-REFERENCE TO RELATED APPLICATION

This application is based on and claims priority under 35 U.S.C. § 119 to Korean Patent Application No. 10-2023-0153100, filed on Nov. 7, 2023, in the Korean Intellectual Property Office, the disclosure of which is incorporated by reference herein in its entirety.

### BACKGROUND

The inventive concepts relate to semiconductor devices, and more particularly, to semiconductor devices having a memory string arranged in a vertical direction.

In an electronic system requiring data storage, there is a need for a semiconductor device capable of storing high-capacity data. As one of the methods of increasing a data storage capacity of a semiconductor device, a semiconductor device including three-dimensionally arranged memory cells instead of two-dimensionally arranged memory cells has been proposed. In addition, a semiconductor device has been proposed by forming a part of the semiconductor device on a first substrate, forming another part of the semiconductor device on a second substrate, and bonding the first substrate and the second substrate to each other.

### SUMMARY

The inventive concepts provide semiconductor devices having excellent operating characteristics and an improved degree of integration.

According to an example embodiment of the inventive concepts, a semiconductor device may include a peripheral circuit structure, a cell structure including gate electrodes and stacked on the peripheral circuit structure and including a cell region, a connection region, and a peripheral circuit connection region,, a plurality of channel structures extending in a vertical direction through the gate electrodes in the cell region, each of the plurality of channel structures including a first end portion close to the peripheral circuit structure and a second end portion opposite to the first end portion, and a common source layer connected to the second end portion of each of the channel structures in the cell region, wherein the common source layer includes a stack isolation trench extending in a first horizontal direction, and a plurality of channel trenches extending in the first horizontal direction and spaced apart from each other with the stack isolation trench therebetween, in a second horizontal direction perpendicular to the first horizontal direction.

According to an example embodiment of the inventive concepts, a semiconductor device may include a substrate, a peripheral circuit structure on the substrate, a cell structure including gate electrodes and stacked on the peripheral circuit structure, the cell structure including a cell region, a connection region, and a peripheral circuit connection region, a plurality of channel structures extending in a vertical direction through the gate electrodes in the cell region, each of the plurality of channel structures including a first end portion close to the peripheral circuit structure and a second end portion opposite to the first end portion, and a common source layer connected to the second end portion of each of the plurality of channel structures in the cell region, wherein the common source layer includes a stack isolation trench extending in a first horizontal direction, and a plurality of channel trenches extending in the first horizontal direction and spaced apart from each other with the stack isolation trench therebetween, in a second horizontal direction perpendicular to the first horizontal direction, and wherein each of the plurality of channel structures includes a cylindrical channel layer extending in the vertical direction, and a charge storage layer and a blocking dielectric layer sequentially stacked on an outer wall of the cylindrical channel layer.

According to an example embodiment of the inventive concepts, a semiconductor device may include a substrate, a peripheral circuit structure on the substrate, a cell structure including gate electrodes and stacked on the peripheral circuit structure, the cell structure including a cell region, a connection region, and a peripheral circuit connection region, a plurality of channel structures extending in a vertical direction through the gate electrodes in the cell region, each of the plurality of channel structures including a first end portion close to the peripheral circuit structure and a second end portion opposite to the first end portion, and a common source layer connected to the second end portion of each of the plurality of channel structures in the cell region, a conductive laminate in contact with a top surface of the common source layer, a sidewall of the conductive laminate being coplanar with a sidewall of the common source layer, wherein the common source layer includes a stack isolation trench extending in a first horizontal direction, and a plurality of channel trenches extending in the first horizontal direction, spaced apart from each other with the stack isolation trench therebetween, in a second horizontal direction perpendicular to the first horizontal direction, each of the plurality of channel trenches having a narrower width in the second horizontal direction than the stack isolation trench, and wherein each of the plurality of channel structures includes a cylindrical channel layer extending in the vertical direction, and a charge storage layer and a blocking dielectric layer sequentially stacked on an outer sidewall of the cylindrical channel layers, the charge storage layer including a ferroelectric material.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram of a semiconductor device according to an example embodiment;

FIG. 2 is a circuit diagram illustrating a memory block according to an example embodiment;

FIG. 3 is a perspective view illustrating a representative configuration of a semiconductor device according to an example embodiment;

FIG. 4 is a planar layout diagram of the semiconductor device of FIG. 3;

FIG. 5 is an enlarged layout diagram of portion A of FIG. 4;

FIG. 6 is a plan view of a common source layer of a semiconductor device according to an example embodiment;

FIG. 7 is a cross-sectional view taken along line B1-B1′ and line B2-B2′ of FIG. 5;

FIG. 8 is an enlarged view of portion CX1 of FIG. 7;

FIG. 9 is a plan view of a common source layer of a semiconductor device according to an example embodiment;

FIG. 10 is a cross-sectional view of a semiconductor device according to an example embodiment;

FIG. 11 is an enlarged view of a portion CX2 of FIG. 10.

FIG. 12 is a plan view of a common source layer of a semiconductor device according to an example embodiment;

FIG. 13 is a cross-sectional view of a semiconductor device according to an example embodiment;

FIG. 14 is an enlarged view of portion CX3 of FIG. 13;

FIGS. 15 to 21 are cross-sectional views sequentially illustrating a method of manufacturing a semiconductor device, according to an example embodiment;

FIG. 22 is a diagram schematically illustrating a data storage system including a semiconductor device according to an example embodiment;

FIG. 23 is a perspective view schematically illustrating a data storage system including a semiconductor device according to an example embodiment; and

FIG. 24 is a cross-sectional view schematically illustrating semiconductor packages according to an example embodiment.

### DETAILED DESCRIPTION

Hereinafter, some example embodiments of the inventive concepts will be described in detail with reference to the accompanying drawings. However, the inventive concepts does not have to be configured as limited to the example embodiments described below, and may be embodied in various other forms. Accordingly, the following example embodiments are merely some examples provided to sufficiently convey the scope of the inventive concepts to those skilled in the art.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

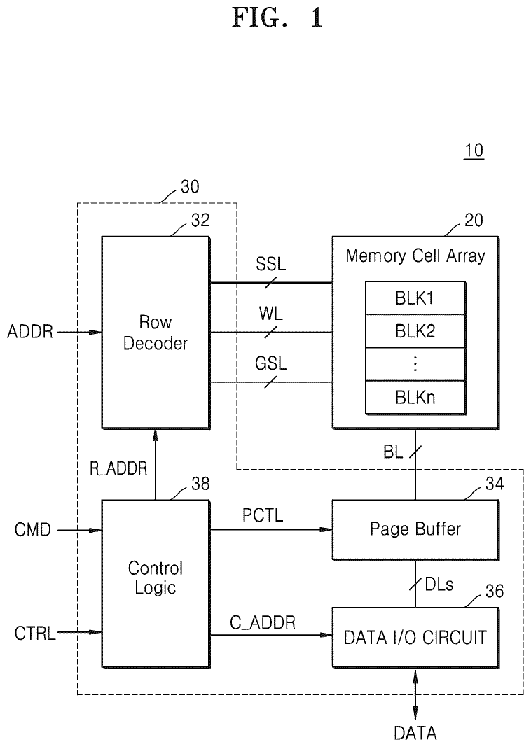

FIG. 1 is a block diagram of a semiconductor device 10 according to an example embodiment.

Referring to FIG. 1, the semiconductor device 10 may include a memory cell array 20 and a peripheral circuit 30. The memory cell array 20 includes a plurality of memory cell blocks BLK1, BLK2, . . . , and BLKn. Each of the plurality of memory cell blocks BLK1, BLK2, . . . , and BLKn may include a plurality of memory cells. The memory cell blocks BLK1, BLK2, and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output circuit 36, and a control logic 38. Although not shown in FIG. 1, the peripheral circuit 30 may further include an input/output interface, a column logic, a voltage generation unit, a pre-decoder, a temperature sensor, a command decoder, an address decoder, an amplification circuit, and the like.

The memory cell array 20 may be coupled to the page buffer 34 through the bit line BL and may be coupled to the row decoder 32 through the word line WL, the string selection line SSL, and the ground selection line GSL. In the memory cell array 20, the plurality of memory cells included in each of the plurality of memory cell blocks BLK1, BLK2, . . . , and BLKn may be flash memory cells. The memory cell array 20 may include a three-dimensional memory cell array. The three-dimensional memory cell array may include a plurality of NAND strings, and each NAND string may include a plurality of memory cells connected to a plurality of word lines WL vertically stacked on a substrate.

The peripheral circuit 30 may receive an address ADDR, a command CMD, and a control signal CTRL from the outside of the semiconductor device 10 and may transmit and receive data DATA to and from a device outside the semiconductor device 10.

The row decoder 32 may select at least one of the plurality of memory cell blocks BLK1, BLK2, . . . , and BLKn in response to an address ADDR from the outside and may select a word line WL, a string selection line SSL, and a ground selection line GSL of the selected memory cell block. The row decoder 32 may transmit a voltage for performing a memory operation to the word line WL of the selected memory cell block.

The page buffer 34 may be connected to the memory cell array 20 through a bit line BL. During a program operation, the page buffer 34 may operate as a write driver and apply, to the bit line BL, a voltage according to data DATA to be stored in the memory cell array 20, and during a read operation, the page buffer 34 may operate as a sense amplifier to detect the data DATA stored in the memory cell array 20. The page buffer 34 may operate according to a control signal PCTL provided from the control logic 38.

The data input/output circuit 36 may be connected to the page buffer 34 through data lines DLs. The data input/output circuit 36 may receive data DATA from a memory controller (not shown) during a program operation and may provide program data DATA to the page buffer 34 based on the column address C_ADDR provided from the control logic 38. The data input/output circuit 36 may provide the read data DATA stored in the page buffer 34 to the memory controller based on the column address C_ADDR provided from the control logic 38 during a read operation.

The memory controller may transmit an input address or command to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and a column address C_ADDR to the data input/output circuit 36. The control logic 38 may generate various internal control signals used in the semiconductor device 10 in response to the control signal CTRL. For example, the control logic 38 may adjust a voltage level provided to the word line WL and the bit line BL when performing a memory operation such as a program operation or an erase operation.

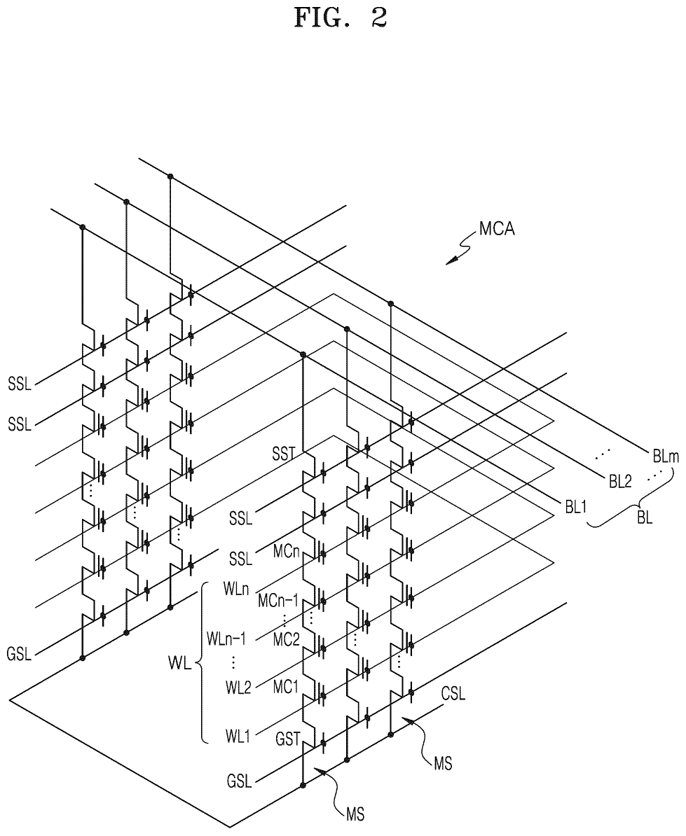

FIG. 2 is a circuit diagram illustrating a memory block according to an example embodiment.

Referring to FIG. 2, a memory cell array MCA may include a plurality of memory cell strings MS. The memory cell array MCA may include a plurality of bit lines BL: BL1, BL2, . . . , and BLm, a plurality of word lines WL: WL1, WL2, . . . , WLn-1, and WLn, at least one string selection line SSL, at least one ground selection line GSL, and a common source line CSL. A plurality of memory cell strings MS may be formed between the plurality of bit lines BL: BL1, BL2, . . . , and BLm and the common source line CSL. Although FIG. 2 illustrates a case where each of the plurality of memory cell strings MS includes two string selection lines SSL, the inventive concepts are not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn-1, and MCn. The drain region of the string selection transistor SST may be connected to the bit lines BL: BL1, BL2, . . . , and BLm, and the source region of the ground selection transistor GST may be connected to the common source line CSL. The common source line CSL may be a region in which source regions of a plurality of ground selection transistors GST are commonly connected.

The string selection transistor SST may be connected to the string selection line SSL, and the ground selection transistor GST may be connected to the ground selection line GSL. A plurality of memory cell transistors MC1, MC2, . . . , MCn-1, and MCn may be connected to a plurality of word lines WL: WL1, WL2, . . . , WLn-1, and WLn, respectively.

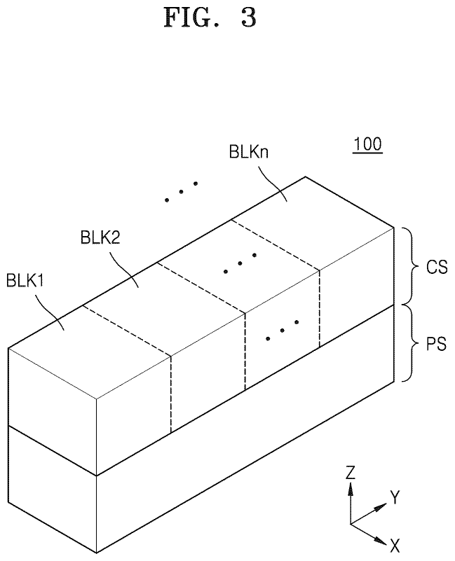

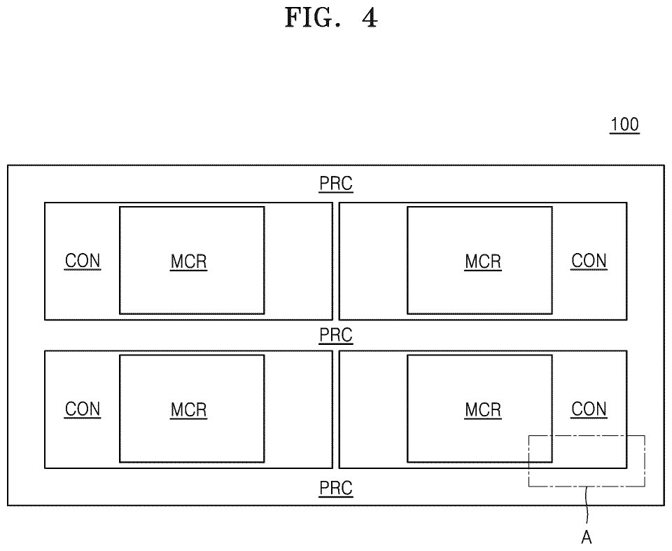

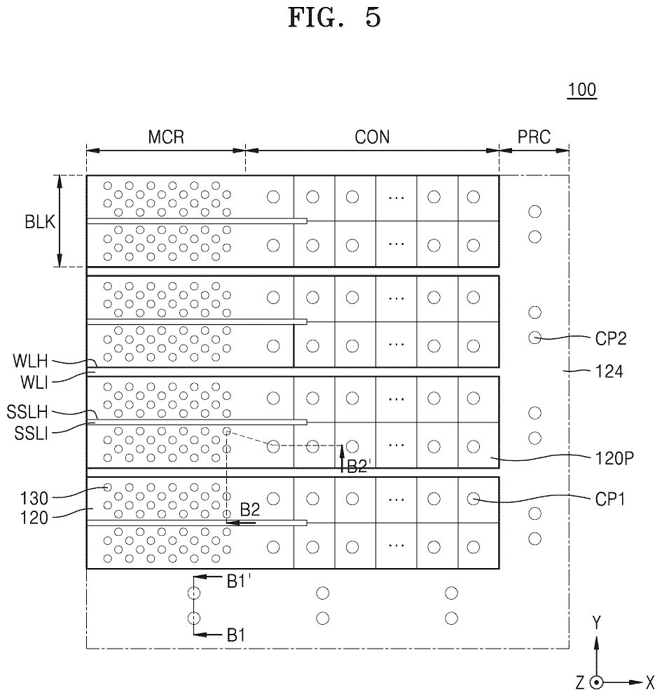

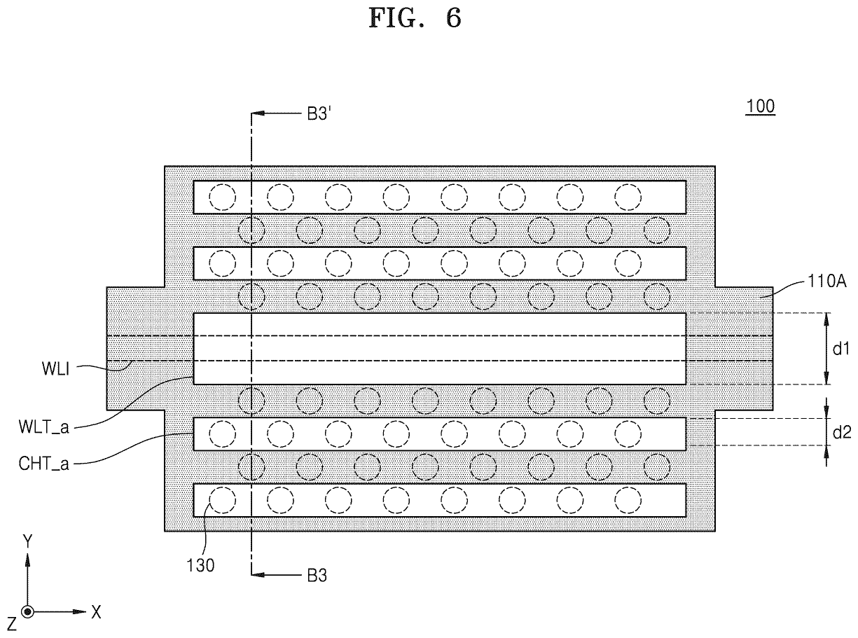

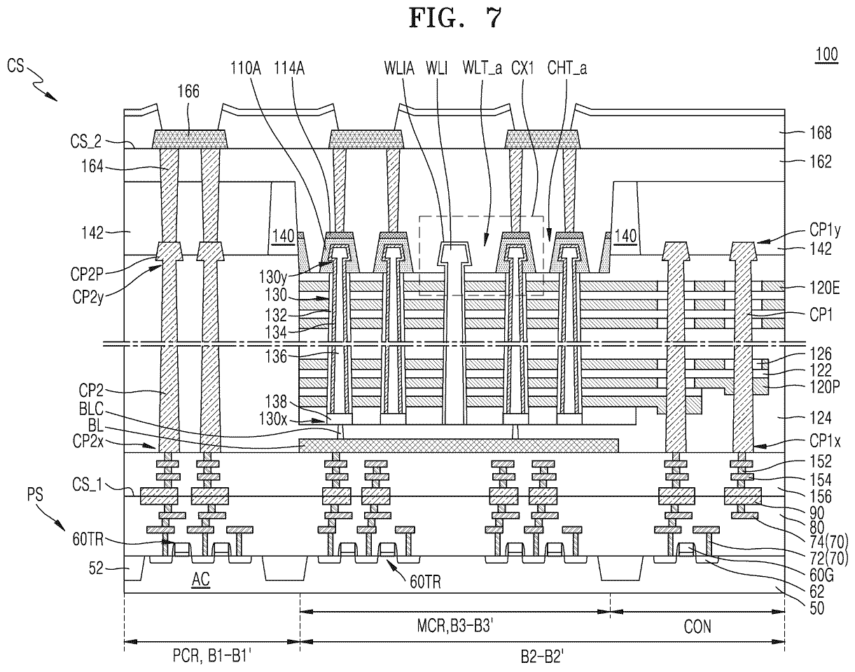

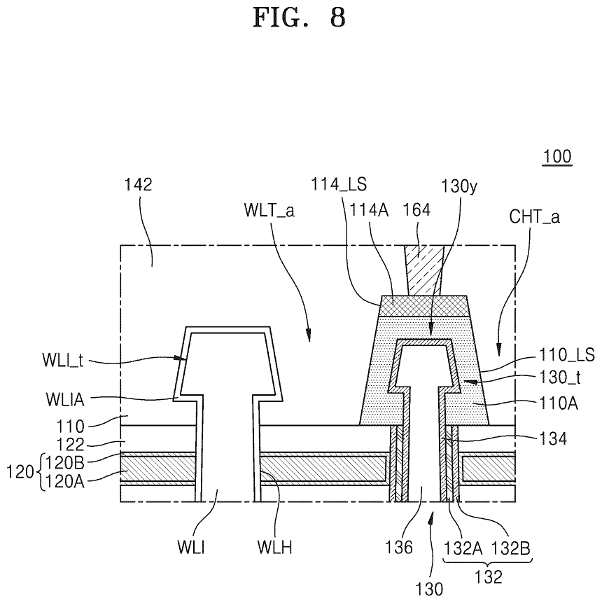

FIG. 3 is a perspective view illustrating a representative configuration of a semiconductor device 100 according to an example embodiment. FIG. 4 is a planar layout diagram of the semiconductor device 100 of FIG. 3. FIG. 5 is an enlarged layout diagram of portion A of FIG. 4. FIG. 6 is a plan view of a common source layer 110A of a semiconductor device 100 according to an example embodiment. FIG. 7 is a cross-sectional view taken along line B1-B1′ and line B2-B2′ of FIG. 5, and FIG. 8 is an enlarged view of portion CX1 of FIG. 7.

Referring to FIGS. 3 to 8, the semiconductor device 100 includes a cell structure CS and a peripheral circuit structure PS, which overlap each other in a vertical direction (Z-direction). The cell structure CS may include the memory cell array 20 described with reference to FIG. 1, and the peripheral circuit structure PS may include the peripheral circuit 30 described with reference to FIG. 1.

The cell structure CS may include a plurality of memory cell blocks BLK1, BLK2, and BLKn. Each of the plurality of memory cell blocks BLK1, BLK2, . . . , and BLKn may include three-dimensionally arranged memory cells.

The peripheral circuit structure PS may include a peripheral circuit transistor 60TR and a peripheral circuit wiring structure 70 arranged on a substrate 50. An active region AC may be defined in the substrate 50 by a device isolation layer 52, and the plurality of peripheral circuit transistors 60TR may be formed on the active region AC. The plurality of peripheral circuit transistors 60TR may include a peripheral circuit gate 60G and a source/drain region 62 arranged in a portion of the substrate 50 on both sides of the peripheral circuit gate 60G.

The substrate 50 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 50 may be provided as a bulk wafer or an epitaxial layer. In another example embodiment, the substrate 50 may include a silicon-on-insulator (SOI) substrate or a germanium-on-insulator (GeOI) substrate.

The peripheral circuit wiring structure 70 includes a plurality of peripheral circuit contacts 72 and a plurality of peripheral circuit wiring layers 74. An interlayer insulating layer 80 covering the peripheral circuit transistor 60TR and the peripheral circuit wiring structure 70 may be arranged on the substrate 50. The plurality of peripheral circuit wiring layers 74 may have a multilayer structure including a plurality of metal layers arranged at different vertical levels. Connection pads 90 may be arranged on the interlayer insulating layer 80, and the peripheral circuit structure PS and the cell structure CS may be electrically connected and bonded to each other by the connection pads 90.

The cell structure CS may include a cell region MCR, a connection region CON, and a peripheral circuit connection region PRC. The cell region MCR may be a region in which a memory cell block BLK including a plurality of memory cell strings extending in a vertical direction (Z direction) is arranged. A common source layer 110, a plurality of gate electrodes 120, and a channel structure 130 extending in a vertical direction (Z direction) through the gate electrodes 120 and connected to the common source layer 110 may be arranged in the cell region MCR. An extension part 120E and a pad part 120P connected to each of the plurality of gate electrodes 120 and a first plug CP1 penetrating the extension part 120E and the pad part 120P to be electrically connected to the pad part 120P may be arranged in the connection region CON. A second plug CP2 extending in a vertical direction (Z direction) and electrically connected to the peripheral circuit wiring structure 70 may be arranged in the peripheral circuit connection region PCR.

The cell structure CS may include a first surface CS_1 connected to the peripheral circuit structure PS and a second surface CS_2 opposite to the first surface CS_1. In FIG. 7, it is illustrated that the first surface CS_1 of the cell structure CS is arranged at a lower side of the cell structure CS and the second surface CS_2 of the cell structure CS is arranged at an upper side of the cell structure CS. Here, for convenience, those arranged close to the first surface CS_1 of the cell structure CS are referred to as being arranged at a lower vertical level, and those arranged close to the second surface CS_2 of the cell structure CS are referred to as being arranged at a higher vertical level.

As illustrated in FIG. 8, each of the gate electrodes 120 may include a buried conductive layer 120A and a conductive barrier layer 120B surrounding a top surface, a bottom surface, and a side surface of the buried conductive layer 120A. For example, the buried conductive layer 120A may include metal such as tungsten, nickel, cobalt, tantalum, etc., metal silicide such as tungsten silicide, nickel silicide, cobalt silicide, tantalum silicide, etc., doped polysilicon, or a combination thereof. In some example embodiments, the conductive barrier layer 120B may include titanium nitride, tantalum nitride, tungsten nitride, or a combination thereof.

In some example embodiments, the gate electrodes 120 may correspond to a ground selection line GSL (see FIG. 2), a word line WL: WL1, WL2, . . . , WLn-1, and WLn (see FIG. 2) and at least one string selection line SSL (see FIG. 2), which constitute the memory cell string MS (see FIG. 2). For example, the uppermost gate electrode 120 may function as a ground selection line GSL, the lowermost two gate electrodes 120 may function as string selection lines SSL, and the remaining gate electrodes 120 may function as word lines WL. Accordingly, a memory cell string MS in which the ground selection transistor GST, the string selection transistor SST, and the memory cell transistors MC1, MC2, . . . , MCn-1, and MCn connected in series between the ground selection transistor GST and the string selection transistor SST may be provided. In some example embodiments, at least one of the gate electrodes 120 may function as a dummy word line, but is not limited thereto.

A stack isolation insulating layer WLI may be arranged in a stack isolation opening WLH that penetrates the gate electrodes 120 and the mold insulating layers 122 and extends in the vertical direction (Z direction). The stack isolation insulating layer WLI may have a top surface arranged at a vertical level higher than that of the uppermost gate electrode 120 and may protrude upward with respect to the uppermost gate electrode 120. As illustrated in FIG. 5, the gate electrodes 120 arranged between a pair of stack isolation openings WLH may constitute one block BLK. In addition, within one block BLK, at least one gate electrode 120 (for example, the lowest gate electrode 120) may be separated into two gate electrodes 120 by a string isolation opening SSLH. A string isolation insulating layer SSLI may be arranged in the string isolation opening SSLH.

A stack insulating layer 124 may be arranged in the connection region CON and the peripheral circuit connection region PCR to surround the gate electrodes 120, the extension parts 120E, and the pad parts 120P. In a plan view, the stack insulating layer 124 may be arranged to surround the gate electrodes 120 and may have a top surface arranged at the higher level as the uppermost gate electrode 120 in the peripheral circuit connection region PCR.

The channel structure 130 may include a first end portion 130x arranged close to the peripheral circuit structure PS, and a second end portion 130y opposite to the first end portion 130x. In some example embodiments, the channel structure 130 may have a sidewall inclined such that the width of the first end portion 130x is greater than the width of the second end portion 130y. The bit line BL may be electrically connected to the first end portion 130x of the channel structure 130 through a bit line contact BLC, and the common source layer 110 may be connected to the second end portion 130y of the channel structure 130.

The channel structure 130 may be arranged in a channel hole 130H extending in a vertical direction through the gate electrodes 120 and the mold insulating layers 122 and may include a gate insulating layer 132, a channel layer 134, a buried insulating layer 136, and a drain region 138. The channel layer 134 may have a cylindrical shape, and the gate insulating layer 132 may be arranged on the outer sidewall of the channel layer 134 and the buried insulating layer 136 may be arranged on the inner sidewall of the channel layer 134. The gate insulating layer 132 may not be arranged on the uppermost surface of the channel layer 134 (e.g., on the top surface of the channel layer 134) arranged on the second end portion 130y of the channel structure 130.

As illustrated in FIG. 8, the gate insulating layer 132 may have a structure sequentially including a charge storage layer 132A and a blocking dielectric layer 132B on an outer sidewall of the channel layer 134. Relative thicknesses of the charge storage layer 132A and the blocking dielectric layer 132B constituting the gate insulating layer 132 are not limited to those illustrated in FIG. 8 and may be variously modified.

According to an example embodiment, the charge storage layer 132A may include a ferroelectric material. For example, the charge storage layer 132A may include at least one of HfO₂, Hf₁₋ₓZrₓO₂ (0 <x≤0.5), Ba₁₋ₓSrₓTiO₃ (0≤x≤0.3), BaTiO₃, or PbZrₓTi₁₋ₓO₃ (0≤x≤0.1). In addition, the charge storage layer 132A may further include impurities, and the impurities may include aluminum (Al), titanium (Ti), tantalum (Ta), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), tin (Sn), or the like.

The blocking dielectric layer 132B may include silicon oxide, silicon nitride, or metal oxide having a higher dielectric constant than silicon oxide. The metal oxide may include a hafnium oxide, an aluminum oxide, a zirconium oxide, a tantalum oxide, or a combination thereof.

The common source layer 110 may be formed on the uppermost mold insulating layer 122 to be connected to the second end portion 130y of the channel structure 130. In a plan view, the common source layer 110 may be arranged over the entire region of the cell region MCR.

According to an example embodiment, the common source layer 110A may include a stack isolation trench WLT_a and a plurality of channel trenches CHT_a. The stack isolation trench WLT_a may extend in a first horizontal direction (X direction), and the stack isolation trench WLT_a may overlap the stack isolation insulating layer WLI in a vertical direction (Z direction). A portion of the stack isolation insulating layer WLI and a portion of an insulating liner WLIA surrounding the stack isolation insulating layer WLI may be exposed inside the stack isolation trench WLT_a.

According to an example embodiment, an upper end portion WLI_t of the stack isolation insulating layer WLI may have a width wider in the lateral direction (e.g., X direction or Y direction) than a lower end portion of the stack isolation insulating layer WLI. The upper end portion WLI_t of the stack isolation insulating layer WLI may have a trapezoidal cross-section in which the width in the lateral direction (e.g., X direction or Y direction) increases downward in the vertical direction (Z direction), that is, toward the peripheral circuit structure PS. The upper end part WLI_t of the stack isolation insulating layer WLI may be exposed through the stack isolation trench WLT_a, and portions of the stacked isolation insulating layer WLI, which are not exposed through the stack isolation trench WLT_a and buried in the mold insulation layer 122, and the gate electrodes 120, which are stacked, may have a smaller width in a lateral direction (e.g., an X direction or a Y direction) than the upper end portion WLI_t.

As illustrated in FIG. 6, the stack isolation trench WLT_a may have a first width d1 in the second horizontal direction (Y direction) that is constant in the first horizontal direction (X direction), and the stack isolation trench WLT_a may have a width in the second horizontal direction (Y direction) that is wider than the stack isolation insulating layer WLI.

According to an example embodiment, a plurality of channel trenches CHT_a may be spaced apart from each other in the second horizontal direction (Y direction) with the stack isolation trench WLT_a therebetween.

According to an example embodiment, an upper end portion 130_t of the channel structure 130 may have a width wider than that of the lower end portion of the channel layer 134, in the lateral direction (e.g., X direction or Y direction). The upper end portion 130_t of the channel structure 130 may have a trapezoidal cross-section in which the width in the lateral direction (e.g., X direction or Y direction) increases downward in the vertical direction (Z direction), that is, toward the peripheral circuit structure PS. Some of the upper end portions 130_t of the plurality of channel structures 130 may overlap the channel trench CHT_a in a vertical direction (Z direction) and may be exposed through the channel trench CHT_a. However, some of the upper end portions 130_t of the plurality of channel structures 130 may not overlap the channel trench CHT_a in the vertical direction (Z direction) and may be buried in the common source layer 110.

As shown in FIG. 6, the channel trench CHT_a may have a second width d2 in the second horizontal direction (Y direction) that is constant in the first horizontal direction (X direction). In this case, the second width d2 of the channel trench CHT_a may be less than the first width d1 of the stack isolation trench WLT_a.

The stack isolation trench WLT_a and the channel trench CHT_a may have a tapered shape in which the width in the lateral direction (e.g., X direction or Y direction) narrows downward in the vertical direction (Z direction), that is, toward the peripheral circuit structure PS. The stack isolation trench WLT_a and the channel trench CHT_a may be formed by etching a conductive laminate 114A and the common source layer 110A through an etching process from top to bottom. According to an example embodiment, the common source layer 110A may overlap and contact the cylindrical channel layer 134 arranged on the second end portion 130y of the channel structure 130 in the vertical direction (Z direction).

According to an example embodiment, the conductive laminate 114A arranged to be in contact with the top surface of the common source layer 110A may be further included. A sidewall 114_LS of the conductive laminate 114A may be coplanar with a sidewall 110_LS of the common source layer 110A. The sidewall 114_LS of the conductive laminate 114A may be inclined away from the center of the channel structure 130 as it goes downward in the vertical direction (Z direction). Likewise, the sidewall 110_LS of the common source layer 110A may also be inclined away from the center of the channel structure 130 downward in the vertical direction (Z direction). The conductive laminate 114A may include titanium nitride, tantalum nitride, tungsten nitride, or a combination thereof. For example, the conductive laminate 114A may include metal such as tungsten, molybdenum, chromium, nickel, cobalt, tantalum, etc., metal silicide such as tungsten silicide, nickel silicide, cobalt silicide, tantalum silicide, or combinations thereof.

According to an example embodiment, the common source layer 110A and the conductive laminate 114A may have a trapezoidal shape in which the width in the lateral direction (X direction or Y direction) increases downward in the vertical direction (Z direction) in a cross-section perpendicular to the top surface of the substrate 50.

According to an example embodiment, an upper interlayer insulating layer 162 to be described below may be buried in the stack isolation trench WLT_a and the channel trench CHT_a. In addition, as described in detail below, a rear pad 166 may be arranged on the upper interlayer insulating layer 162, and a rear via 164 may be formed through the upper interlayer insulating layer 162. The rear via 164 may penetrate the upper interlayer insulating layer 162 to be connected to the rear pad 166 and the conductive laminate 114A. The rear via 164 may serve as the common source line CSL shown in FIG. 2.

As a plurality of trenches WLT_a and CHT_a extending in the vertical direction (Z direction) are formed in the common source layer 110A, the plane area of the common source layer 110A is further reduced from a horizontal point of view. Because the capacitance of the common source layer 110A is proportional to the plane area of the common source layer 110A, the capacitance of the common source layer 110A in which the plurality of trenches WLT_a and CHT_a are formed decreases. This may lead to improvement of the RC delay of the memory cell strings MS.

In some example embodiments, the common source layer 110 may include polysilicon, and a laser annealing process may be performed on the common source layer 110 to have a relatively large grain size and/or relatively good crystal quality. In some example embodiments, as illustrated in FIG. 8, the common source layer 110 may conformally cover the top surface of the gate insulating layer 132.

An insulating wall 140 may be arranged at a boundary between the cell region MCR and the connection region CON. The insulating wall 140 may be arranged to surround the cell region MCR in a plan view and may have a top surface arranged at a vertical level higher than that of the uppermost gate electrode 120. The insulating wall 140 may have a relatively large height, and for example, the height of the insulating wall 140 may be in a range of about 50 nanometers to about 1000 nanometers. In some example embodiments, the insulating wall 140 may include a silicon oxide layer, a silicon nitride layer, SiON, SiOCN, SiCN, or a combination thereof.

An insulating base layer 142 may be arranged in the connection region CON and the peripheral circuit connection region PRC. The insulating base layer 142 may have the same height as the insulating wall 140. For example, the height of the insulating base layer 142 may be in a range of about 50 nanometers to about 1000 nanometers. The insulating base layer 142 may surround the insulating wall 140 in a plan view, and an outer side wall of the insulating wall 140 and the insulating base layer 142 may contact each other. In some example embodiments, the insulating base layer 142 may include a silicon oxide layer, a silicon nitride layer, SiON, SiOCN, SiCN, or a combination thereof.

In the connection region CON, a first plug CP1 may be arranged by penetrating the extension parts 120E and the pad parts 120P extending from the gate electrodes 120. Insulating patterns 126 may be formed at positions vertically overlapping the pad parts 120P connected to the first plug CP1, and the insulating patterns 126 may be arranged between the first plug CP1 and the extension parts 120E.

In some example embodiments, a first end portion CP1x of the first plug CP1 may be arranged at a position adjacent to the peripheral circuit structure PS, and a second end portion CP1y of the first plug CP1 may be arranged opposite to the first end portion CP1x. The first plug CP1 may have an inclined sidewall such that the width of the first end portion CP1x is greater than the width of the second end portion CP1y. The second end portion CP1y of the first plug CP1 may extend through the insulating base layer 142, and a top surface of the second end CP1y of the first plug CP1 may be covered by the insulating base layer 142.

In some example embodiments, the first plug CP1 may include a conductive buried layer and a thin barrier layer surrounding upper and sidewalls of the conductive buried layer. For example, the conductive buried layer may include metal such as tungsten, nickel, cobalt, tantalum, etc., metal silicide such as tungsten silicide, nickel silicide, cobalt silicide, tantalum silicide, etc., doped polysilicon, or a combination thereof. The barrier layer may include titanium nitride, tantalum nitride, tungsten nitride, or a combination thereof.

In the peripheral circuit connection region PRC, a second plug CP2 may be arranged to penetrate the stack insulating layer 124. The first end portion CP2x of the second plug CP2 may be arranged at a position adjacent to the peripheral circuit structure PS, and the second end portion CP2y of the second plug CP2 may be arranged opposite to the first end portion CP2x. The second plug CP2 may have an inclined sidewall such that a width of the first end portion CP2x is greater than a width of the second end portion CP2y. The second end portion CP1y of the second plug CP2 may be in contact with the landing pad CP2P, and at least a portion of the landing pad CP2P may be covered by the insulating base layer 142.

A connection via 152, a connection wiring layer 154, and an interlayer insulating layer 156 surrounding the connection via 152 and the connection wiring layer 154 may be arranged between the stack insulating layer 124 and the peripheral circuit structure PS. The connection via 152 and the connection wiring layer 154 may be formed in multiple layers to be arranged at a plurality of vertical levels, and the bit line BL, the first plug CP1, and the second plug CP2 may be electrically connected to the peripheral circuit structure PS through the connection pad 90.

The upper interlayer insulating layer 162 may be arranged on the common source layer 110 and the insulating base layer 142, the rear vias 164 may pass through the upper interlayer insulating layer 162, and the rear pads 166 may be arranged on the upper interlayer insulating layer 162. At least one of the rear vias 164 may be arranged to penetrate the upper interlayer insulating layer 162 in the cell region MCR to be connected to the top surface of the common source layer 110, and at least one of the rear vias 164 may extend from the peripheral circuit connection region PRC to the inside of the insulating base layer 142 through the stack insulating layer 124 and may be connected to the landing pad CP2P. The rear pads 166 may be connected to the rear vias 164. A passivation layer 168 may be arranged on the upper interlayer insulating layer 162, and an opening of the passivation layer 168 may expose top surfaces of the rear pads 166.

In general, a common source layer is formed by deposition on the top surface of the cell structure in a structure in which the peripheral circuit structure and the cell structure are attached in a bonding manner, and a laser annealing process is performed to promote crystallization of the common source layer. However, the heat caused by the laser annealing process may adversely affect the structures formed in the connection region CON and the peripheral circuit connection region PRC. In addition, an IO plug, a stack through plug, and the like are formed in the connection region CON and the peripheral circuit connection region PRC. As a result, the level difference of the top surfaces is large, and thus the difficulty of an etching process for electrically isolating the common source layer, the IO plug, the through plug, and the like from one another is high.

However, according to the disclosed example embodiments, the insulating wall 140 and the insulating base layer 142 may be arranged in the connection region CON and the peripheral circuit connection region PRC to mitigate or prevent thermal damage to structures formed in the connection region CON and the peripheral circuit connection region PRC during the laser annealing process of the common source layer 110 in the cell region MCR. In addition, because the first plug CP1 and the second plug CP2 may be surrounded by the insulating wall 140 and the insulating base layer 142 before the common source layer 110 is formed, unwanted electrical connection between the common source layer 110 and the first and second plugs CP1 and CP2 may be mitigated or prevented. Therefore, the semiconductor device 100 may have improved electrical characteristics.

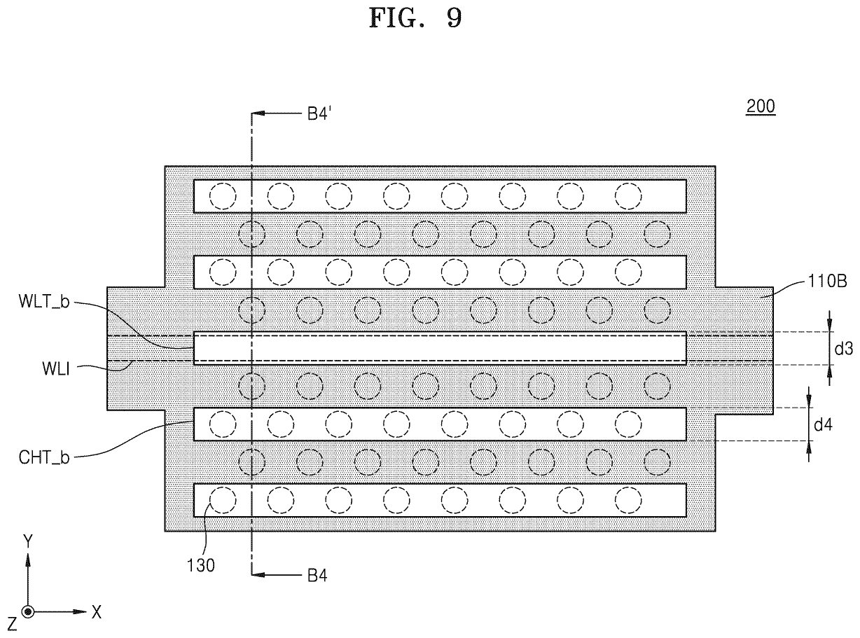

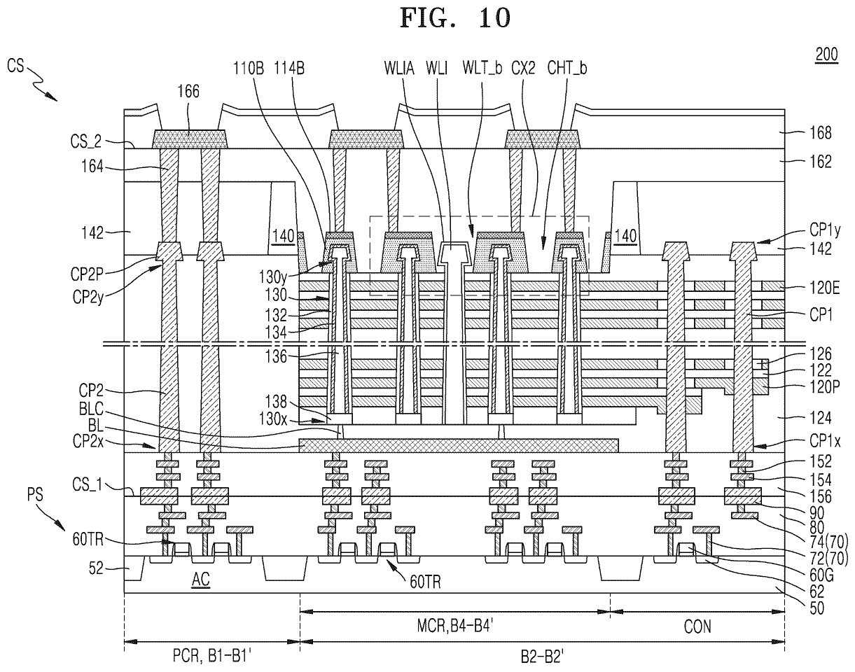

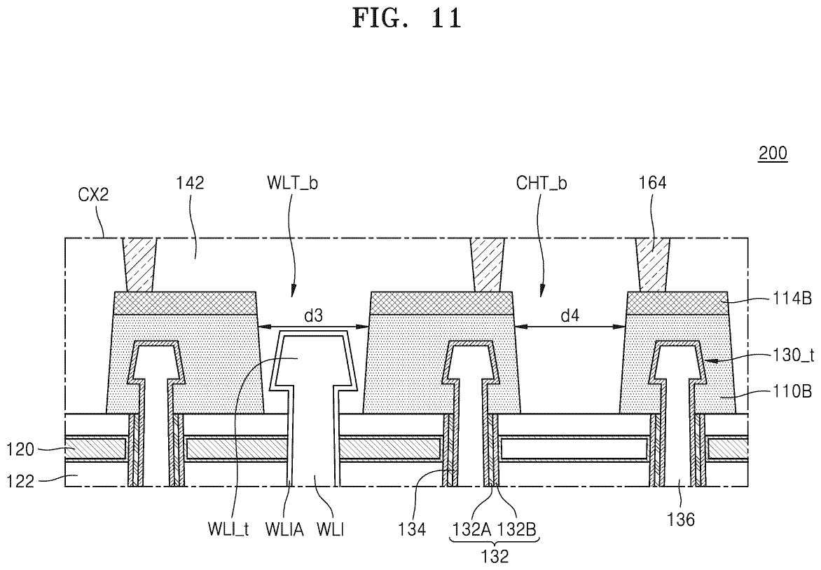

FIG. 9 is a plan view of a common source layer 110B of a semiconductor device 200 according to an example embodiment. FIG. 10 is a cross-sectional view of the semiconductor device 200 according to an example embodiment, and FIG. 11 is an enlarged view of portion CX2 of FIG. 10.

The semiconductor device 200 shown in FIGS. 9 to 11 is substantially the same or similar to the semiconductor device 100 shown in FIGS. 6 to 8, except that the width of the stack isolation trench WLT_b in the lateral direction (e.g., X or Y direction) is the same as the width of the channel trench CHT_b in the lateral direction (e.g., X or Y direction). Accordingly, descriptions of the components described with respect to FIGS. 6 to 8 are omitted or briefly given.

As illustrated in FIG. 9, the stack isolation trench WLT_b may have a third width d3 in the second horizontal direction (Y direction) that is constant in the first horizontal direction (X direction). The stack isolation insulating layer WLI may have a width in the second horizontal direction (Y direction) that is the same as the third width d3 of the stack isolation trench WLT_b. The upper end portion WLI_t of the stack isolation insulating layer WLI may be exposed through the stack isolation trench WLT_b.

According to an example embodiment, a plurality of channel trenches CHT_b may be spaced apart from each other in a second horizontal direction (Y direction) with the stack isolation trench WLT_b therebetween.

Some of the upper end portions 130_t of the plurality of channel structures 130 may overlap the channel trench CHT_b in a vertical direction (Z direction) and may be exposed through the channel trench CHT_b. However, some of the upper end portions 130_t of the plurality of channel structures 130 may not overlap the channel trench CHT_b in the vertical direction (Z direction) and may be buried in the common source layer 110B.

As shown in FIG. 9, the channel trench CHT_b may have a fourth width d4 in the second horizontal direction (Y direction), that is constant in the first horizontal direction (X direction). In this case, the fourth width d4 of the channel trench CHT_b may be the same as the third width d3 of the stack isolation trench WLT_b.

The stack isolation trench WLT_b and the channel trench CHT_b may have a tapered shape in which the width in the lateral direction (e.g., X direction or Y direction) narrows downward in the vertical direction (Z direction), that is, toward the peripheral circuit structure PS. The stack isolation trench WLT_b and the channel trench CHT_b may be formed by etching the conductive laminate 114B and the common source layer 110B through an etching process from top to bottom. According to an example embodiment, the common source layer 110B may overlap and contact the cylindrical channel layer 134 arranged on the second end portion 130y of the channel structure 130 in the vertical direction (Z direction).

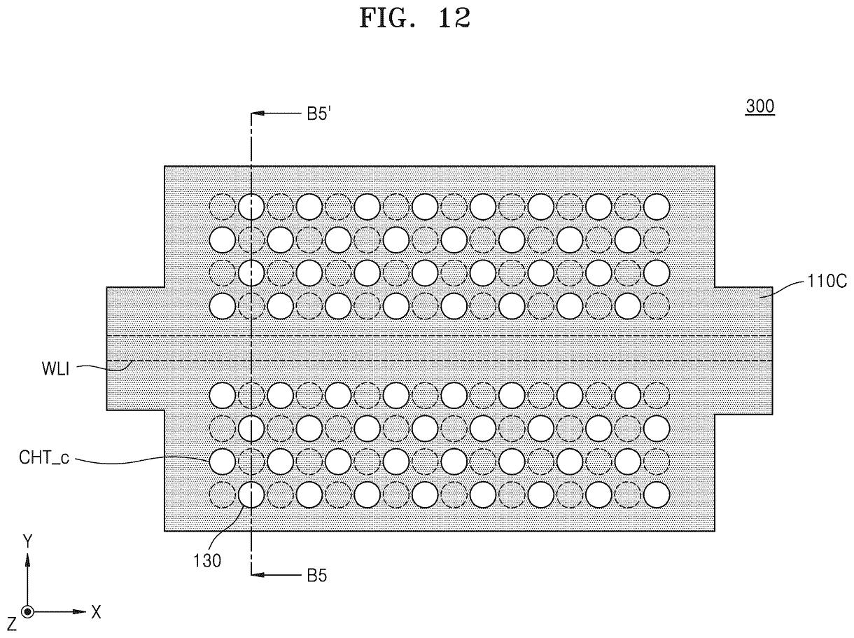

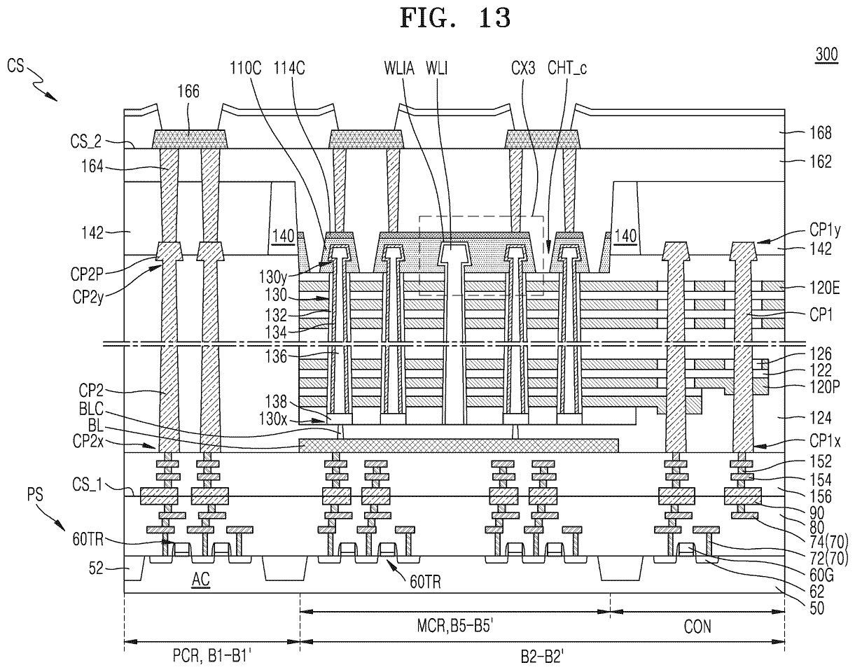

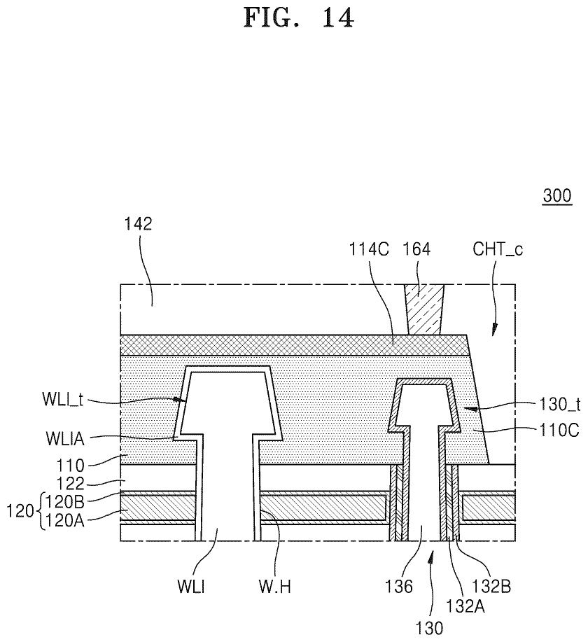

FIG. 12 is a plan view of a common source layer 110C of a semiconductor device 300 according to an example embodiment. FIG. 13 is a cross-sectional view of a semiconductor device 300 according to an example embodiment, and FIG. 14 is an enlarged view of portion CX3 of FIG. 13.

The semiconductor device 300 shown in FIGS. 12 to 14 is substantially the same as or similar to the semiconductor device 100 shown in FIGS. 6 to 8, except that the shape of the channel trench CHT_c shown in FIGS. 12 to 14 is different from the shape of the channel trench CHT_c shown in FIGS. 6 to 8, and the common source layer 110C does not include a trench overlapping the stack isolation insulating layer WLI in the vertical direction (Z-direction). Accordingly, descriptions of the components described with respect to FIGS. 6 to 8 are omitted or briefly given.

As shown in FIG. 12, the common source layer 110C may include a plurality of channel trenches CHT_c formed in a vertical direction (Z direction). In this case, the plurality of channel trenches CHT_c may have a circular shape from a horizontal point of view, and the plurality of channel trenches CHT_c do not overlap the plurality of channel structures 130 in a vertical direction (Z direction). That is, the plurality of channel trenches CHT_c may be formed only in a region where the channel structure 130 is not arranged.

In addition, the common source layer 110C may not include a trench overlapping the stack isolation insulating layer WLI in a vertical direction (Z direction). That is, the upper end portion WLI_t of the stack isolation insulating layer WLI of the semiconductor device 300 may be buried by the common source layer 110C. In addition, the insulating liner WLIA covering the upper end portion WLI_t of the stack isolation insulating layer WLI may contact the common source layer 110C.

The upper end portion 130_t of each of the plurality of channel structures 130 may be buried in the common source layer 110C without overlapping the channel trench CHT_c in the vertical direction (Z direction).

The channel trench CHT_c may have a tapered shape in which the width thereof in the lateral direction (e.g., X direction or Y direction) narrows downward in the vertical direction (Z direction), that is, toward the peripheral circuit structure PS. The stack isolation trench WLT_c and the channel trench CHT_c may be formed by etching the conductive laminate 114C and the common source layer 110C through an etching process from top to bottom. According to an example embodiment, the common source layer 110C may overlap and contact the cylindrical channel layer 134 arranged on the second end portion 130y of the channel structure 130 in the vertical direction (Z direction).

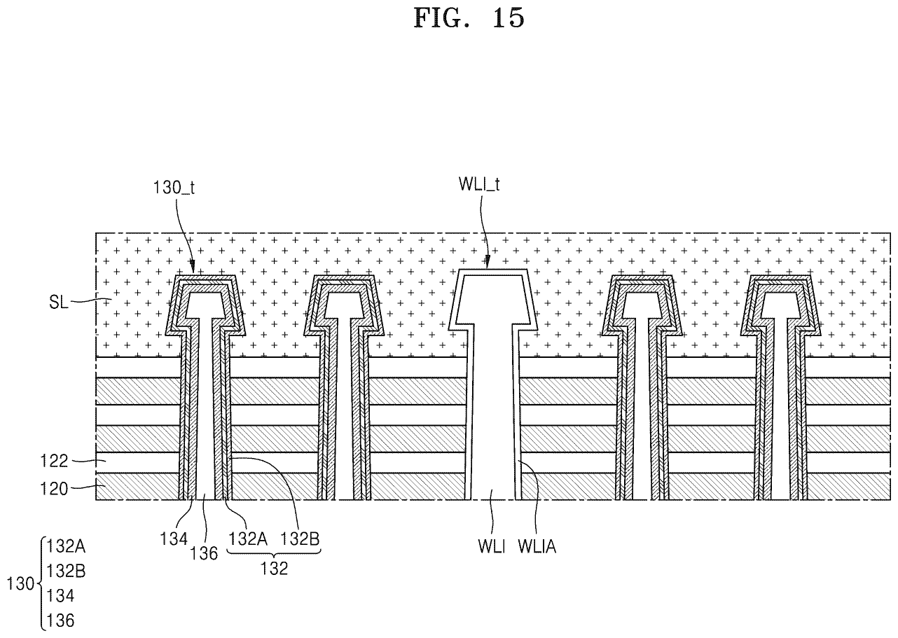

FIGS. 15 to 21 are cross-sectional views sequentially illustrating a method of manufacturing a semiconductor device, according to an example embodiment.

Referring to FIG. 15, the gate electrode 120 and the mold insulating layer 122 may cross and be stacked. In this case, a sacrificial layer SL may be arranged on the uppermost mold insulating layer 122. The plurality of channel structures 130 may pass through the gate electrode 120 and the mold insulating layer 122, and the upper end portion 130_t of each channel structure 130 may be buried in the sacrificial layer SL. In addition, the upper end portion WLI_t of the stack isolation insulating layer WLI may also be buried in the sacrificial layer SL.

The channel structure 130 may include a buried insulating layer 136 extending vertically, a channel layer 134 surrounding the outer wall of the buried insulating layer 136, and a charge storage layer 132A and a blocking dielectric layer 132B surrounding the outer wall of the channel layer 134 in turn. In this case, the blocking dielectric layer 132B may be located at the outermost side of the channel structure 130. In addition, the stack isolation insulating layer WLI may be covered with the insulating liner WLIA having a uniform thickness. The blocking dielectric layer 132B and the insulating liner WLIA may be in contact with the sacrificial layer SL.

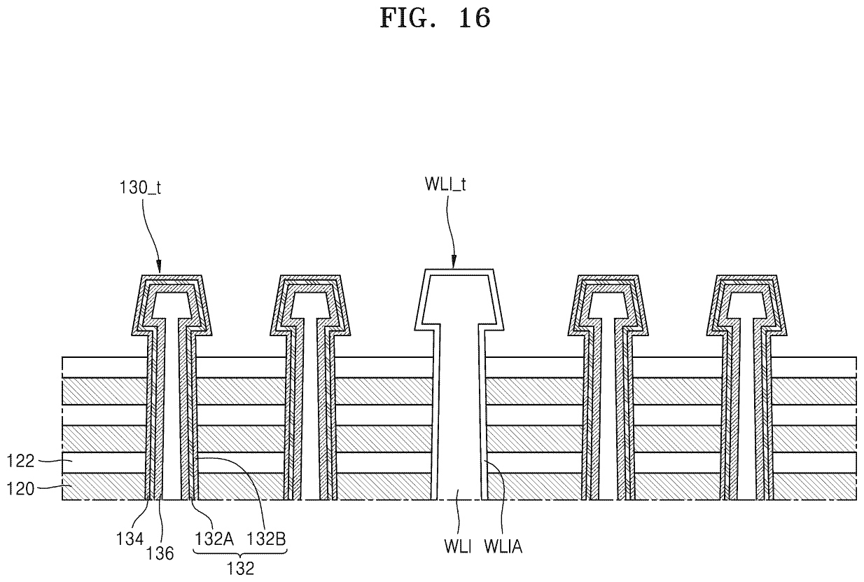

Referring to FIG. 16, the sacrificial layer SL may be removed. In this case, the etching process for removing the sacrificial layer SL may be an etching process using an etching selectivity, and the difference in etching selectivity between the sacrificial layer SL and the uppermost mold insulating layer 122 may be used. As the sacrificial layer SL is removed, the upper end portion 130_t of the channel structure 130 and the upper end portion WLI_t of the stack isolation insulating layer WLI may be exposed to the outside.

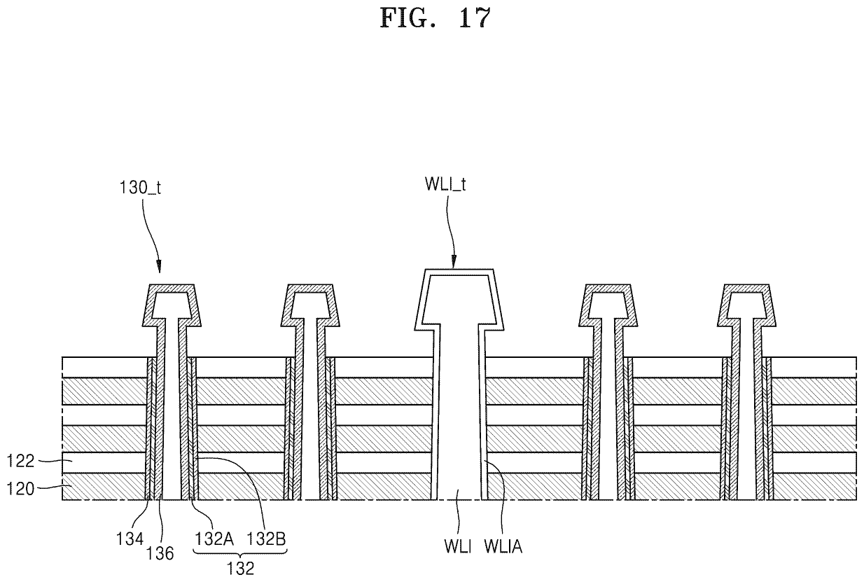

Referring to FIG. 17, a portion of the blocking dielectric layer 132B of the channel structure 130, a portion of the charge storage layer 132A thereof, and a portion of the channel layer 134 thereof may be removed by an etching process. In this case, the portion of the blocking dielectric layer 132B, the portion of the charge storage layer 132A, and the portion of the channel layer 134 may be portions having a higher vertical level than the top surface of the uppermost mold insulating layer 122. That is, when the portion of the blocking dielectric layer 132B, the portion of the charge storage layer 132A, and the portion of the channel layer 134 are removed, the uppermost charge storage layer 132A may serve as a mask. However, when the portion of the blocking dielectric layer 132B, the portion of the charge storage layer 132A, and the portion of the channel layer 134 are removed, the insulating liner WLIA may not be removed. Depending on example embodiments, the insulating liner WLIA may be partially removed, but a relatively small amount may be removed compared to the amount of the blocking dielectric layer 132B, the charge storage layer 132A, and the channel layer 134 removed.

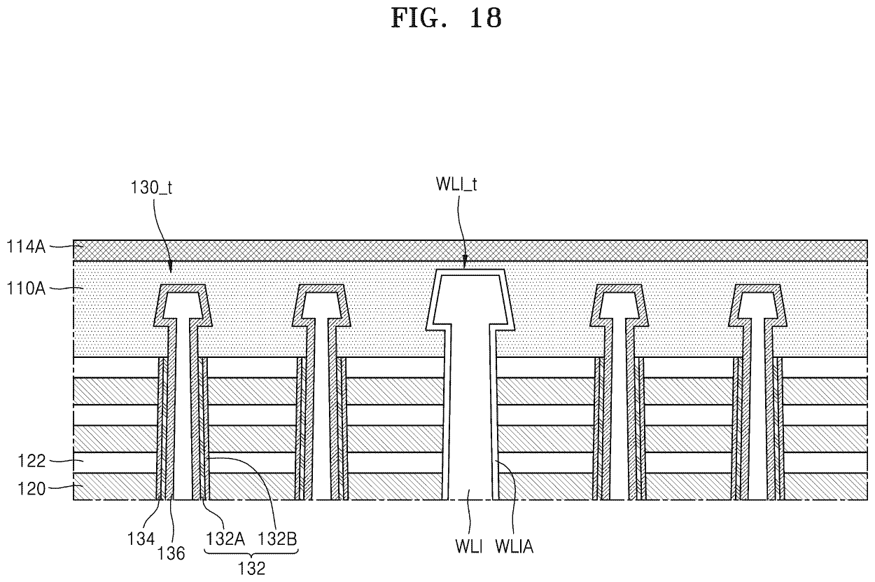

Referring to FIG. 18, the common source layer 110A and a conductive laminate 114A may be formed on the uppermost mold insulation layer 122. The top surface of the common source layer 110A may be formed to have a higher vertical level than the top surface of the channel structure 130 and the top surface of the stack isolation insulating layer WLI. Each of the uppermost mold insulating layer 122 and the common source layer 110A may be formed through a deposition process, and the conductive laminate 114A may be formed to have a uniform thickness. In addition, the top surface of the common source layer 110A may have a flat surface. The upper end portion 130_t of the channel structure 130 and the upper end portion WLI_t of the stack isolation insulating layer WLI may be buried in the common source layer 110A.

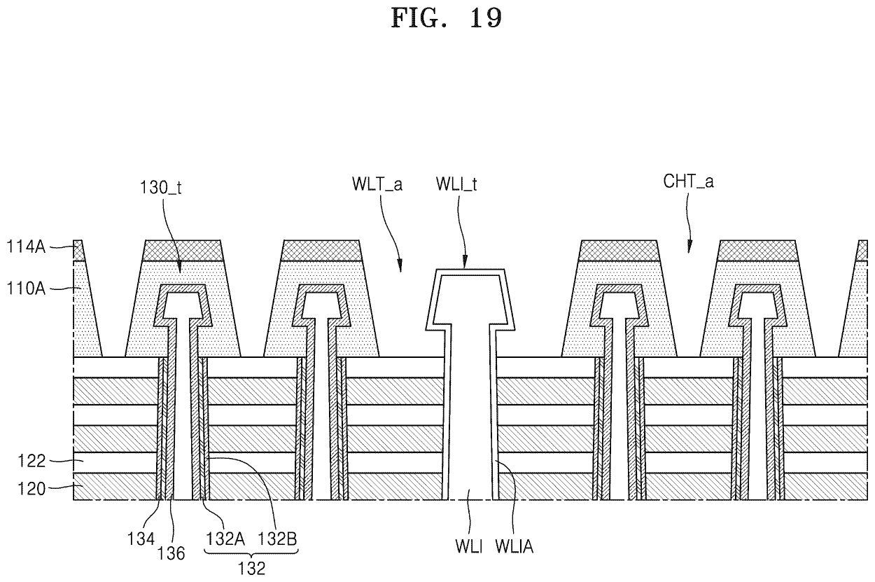

Referring to FIG. 19, the common source layer 110A and the conductive laminate 114A may be partially removed by an etching process to form a stack isolation trench WLT_a and a plurality of channel trenches CHT_a. The stack isolation trench WLT_a and the plurality of channel trenches CHT_a may have a tapered shape in which a width thereof in a lateral direction narrows downward.

According to an example embodiment, the stack isolation trench WLT_a may vertically overlap the stack isolation insulating layer WLI, and the upper end portion WLI_t of the stack isolation insulating layer WLI is exposed to the outside through the stack isolation trench WLT_a. As shown in FIG. 6, some of the plurality of channel structures 130 may vertically overlap the channel trench CHT_a, but some others of the channel structures 130 may not vertically overlap the channel trench CHT_a.

Among the channel structures 130, the upper end portion 130_t of the channel structure 130 that does not vertically overlap the channel trench CHT_a may be buried in the common source layer 110A.

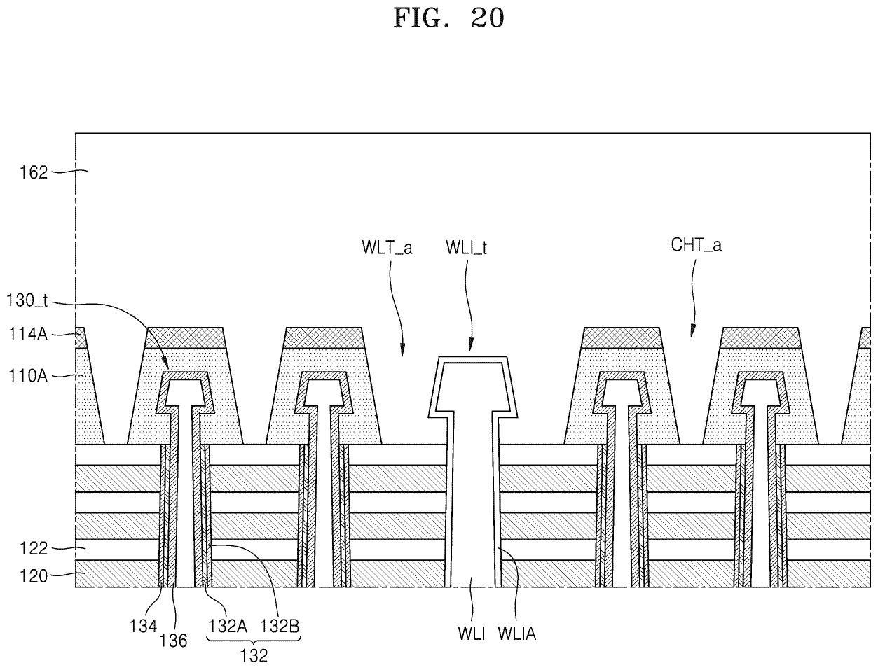

Referring to FIG. 20, the upper interlayer insulating layer 162 filling the stack isolation trench WLT_a and the channel trench CHT_a may be formed. The upper interlayer insulating layer 162 may completely fill the stack isolation trench WLT_a and the channel trench CHT_a, and the top surface of the upper interlayer insulating layer 162 may have a vertical level higher than the top surface of the conductive laminate 114A. The upper interlayer insulating layer 162 may be formed by a deposition process such as a chemical vapor deposition method, a physical vapor deposition method, or an atomic layer deposition method.

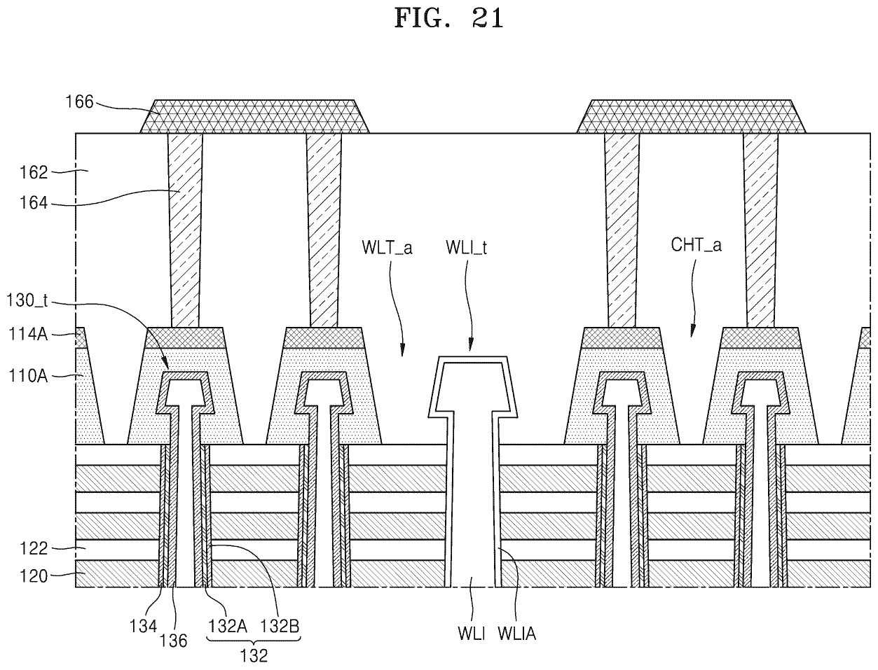

Referring to FIG. 21, the upper interlayer insulating layer 162 may be partially removed by an etching process to form a via hole extending to the conductive laminate 114A, and then the via hole may be filled with a conductive material to form the rear via 164. The rear via 164 may be formed through a plating process. After the rear via 164 is formed, the rear pad 166 may be formed on the top surface of the upper interlayer insulating layer 162. In this case, the rear pad 166 may be arranged to be connected to the rear via 164. The rear pad 166 may have a width sufficient to be connected to at least two rear vias 164 in the lateral direction.

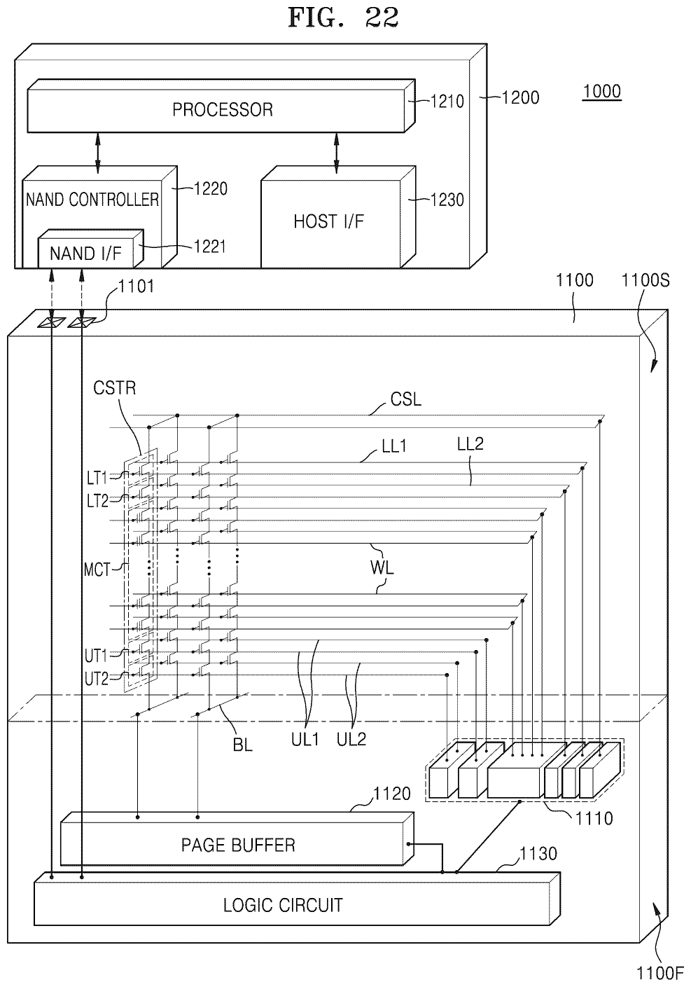

FIG. 22 is a diagram schematically illustrating a data storage system including a semiconductor device according to an example embodiment.

Referring to FIG. 22, a data storage system 1000 may include one or more semiconductor devices 1100 and a memory controller 1200 electrically connected to the semiconductor devices 1100. The data storage system 1000 may be, for example, a solid state drive device (SSD), a universal serial bus (USB) device, a computing system, a medical device, or a communication device, which includes at least one semiconductor device 1100.

The semiconductor device 1100 may be a nonvolatile semiconductor device, and for example, the semiconductor device 1100 may be a NAND flash semiconductor device including one of the semiconductor devices 100, 200, and 300 described with reference to FIGS. 1 to 14. The semiconductor device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including a bit line BL, a common source line CSL, a plurality of word lines WL, first and second string selection lines UL1 and UL2, first and second ground selection lines LL1 and LL2, and a plurality of memory cell strings CSTR between the bit line BL and the common source line CSL.

In the second structure 1100S, each of the plurality of memory cell strings CSTR may include ground selection transistors LT1 and LT2 adjacent to the common source line CSL, string selection transistors UT1 and UT2 adjacent to the bit line BL, and a plurality of memory cell transistors MCT arranged between the ground selection transistors LT1 and LT2 and the string selection transistors UT1 and UT2. The number of ground selection transistors LT1 and LT2 and the number of string selection transistors UT1 and UT2 may be variously modified according to example embodiments.

In some example embodiments, each of the plurality of ground selection lines LL1 and LL2 may be connected to a gate electrode of each of the ground selection transistors LT1 and LT2. The word line WL may be connected to a gate electrode of the memory cell transistor MCT. The plurality of string selection lines UL1 and UL2 may be connected to gate electrodes of string selection transistors UT1 and UT2, respectively.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The semiconductor device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In some example embodiments, the data storage system 1000 may include a plurality of semiconductor devices 1100, and in this case, the memory controller 1200 may control the plurality of semiconductor devices 1100.

The processor 1210 may control the overall operation of the data storage system 1000 including the memory controller 1200. The processor 1210 may operate according to a desired (or alternatively, predetermined) firmware and may access the semiconductor device 1100 by controlling the NAND controller 1220. The NAND controller 1220 may include a NAND interface 1221 that performs communication with the semiconductor device 1100. A control command for controlling the semiconductor device 1100, data to be written to the plurality of memory cell transistors MCT of the semiconductor device 1100, data to be read from the plurality of memory cell transistors MCT of the semiconductor device 1100, and the like may be transmitted through the NAND interface 1221. The host interface 1230 may provide a communication function between the data storage system 1000 and an external host. When a control command is received from an external host through the host interface 1230, the processor 1210 may control the semiconductor device 1100 in response to the control command.

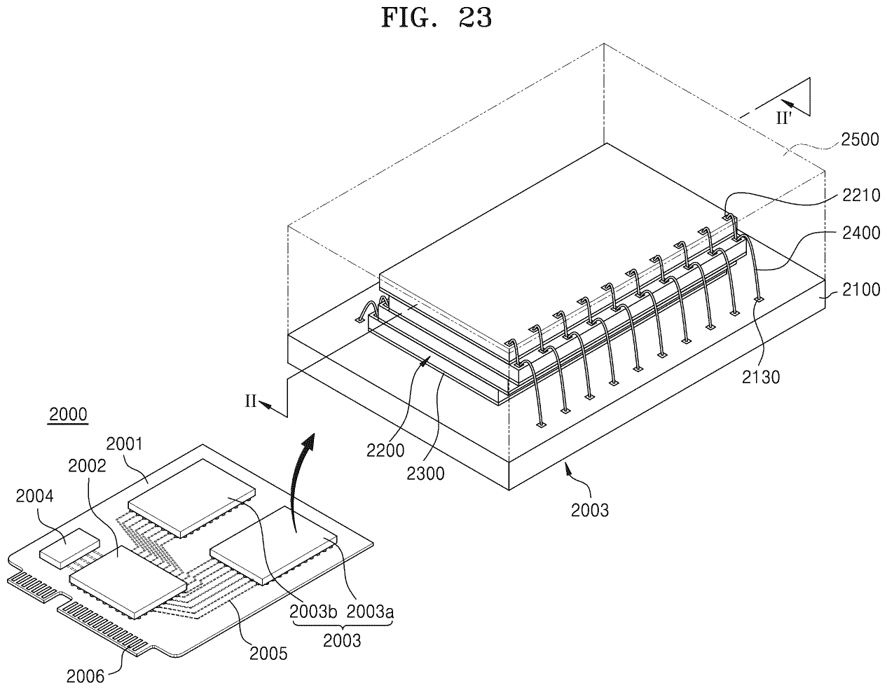

FIG. 23 is a perspective view schematically illustrating a data storage system including a semiconductor device according to an example embodiment.

Referring to FIG. 23, a data storage system 2000 according to an example embodiment may include a main board 2001, a memory controller 2002 mounted on the main board 2001, one or more semiconductor packages 2003, and DRAM 2004. The semiconductor packages 2003 and the DRAM 2004 may be connected to the memory controller 2002 by a plurality of wiring patterns 2005 formed on the main board 2001.

The main board 2001 may include a connector 2006 including a plurality of pins coupled with external hosts. The number and arrangement of the plurality of pins in the connector 2006 may vary according to a communication interface between the data storage system 2000 and the external host. In some example embodiments, the data storage system 2000 may communicate with an external host according to any one of interfaces such as Universal Serial Bus (USB), peripheral component interconnect express (PCI-Express), Serial Advanced Technology Attachment (SATA), M-Phy for Universal Flash Storage (UFS), or the like. In some example embodiments, the data storage system 2000 may operate by power supplied from an external host via the connector 2006. The data storage system 2000 may further include a power management integrated circuit (PMIC) that distributes power supplied from the external host to the memory controller 2002 and the semiconductor package 2003.

The memory controller 2002 may write data to or read data from the semiconductor package 2003 and may improve the operation speed of the data storage system 2000.

The DRAM 2004 may be a buffer memory for alleviating the difference in speed between the semiconductor package 2003, which is a data storage space, and an external host. The DRAM 2004 included in the data storage system 2000 may operate as a kind of cache memory and may provide a space for temporarily storing data in a control operation for the semiconductor package 2003. When the data storage system 2000 includes the DRAM 2004, the memory controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package board 2100, a plurality of semiconductor chips 2200 on the package board 2100, an adhesive layer 2300 arranged on a bottom surface of each of the plurality of semiconductor chips 2200, a connection structure 2400 electrically connecting the plurality of semiconductor chips 2200 to the package board 2100, and a molding layer 2500 covering the plurality of semiconductor chips 2200 and the connection structure 2400 on the package board 2100.

The package board 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 22. Each of the plurality of semiconductor chips 2200 may include at least one of the semiconductor devices 100, 200, and 300 described with reference to FIGS. 1 to 14.

In some example embodiments, the connection structure 2400 may be a bonding wire electrically connecting the input/output pad 2210 to the package upper pad 2130. Therefore, in the first and second semiconductor packages 2003a and 2003b, the plurality of semiconductor chips 2200 may be electrically connected to each other in a bonding wire manner and may be electrically connected to the package upper pad 2130 of the package board 2100. In some example embodiments, in the first and second semiconductor packages 2003a and 2003b, the plurality of semiconductor chips 2200 may be electrically connected to each other by a connection structure including a through silicon via (TSV) instead of a bonding wire-type connection structure 2400.

In some example embodiments, the memory controller 2002 and the plurality of semiconductor chips 2200 may be included in one package. In an example embodiment, the memory controller 2002 and the plurality of semiconductor chips 2200 may be mounted on a separate interposer board different from the main board 2001, and the memory controller 2002 and the plurality of semiconductor chips 2200 may be connected to each other by wiring formed on the interposer board.

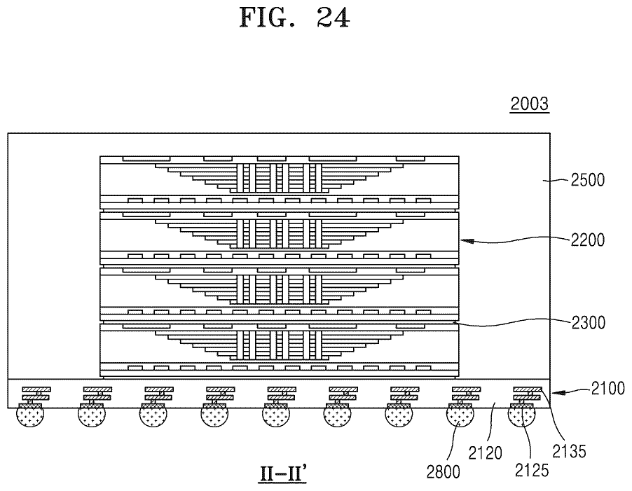

FIG. 24 is a cross-sectional view schematically illustrating semiconductor packages 2003 according to an example embodiment.

Referring to FIG. 24, in the semiconductor package 2003, the package board 2100 may be a printed circuit board. The package board 2100 may include a package board body portion 2120, a plurality of package upper pads 2130 (see FIG. 23) arranged on a top surface of the package board body 2120, a plurality of lower pads 2125 arranged on a bottom surface of the package board body 2120 or exposed through the bottom surface thereof, and a plurality of internal wirings 2135 electrically connecting the plurality of package upper pads 2130 (see FIG. 23) with the plurality of lower pads 2125 inside the package board body 2120. As shown in FIG. 24, the plurality of lower pads 2125 may be connected to a plurality of wiring patterns 2005 on the main board 2001 of the data storage system 2000 shown in FIG. 23 through a plurality of conductive bumps 2800. Each of the plurality of semiconductor chips 2200 may include at least one of the semiconductor devices 100, 200, or 300 described with reference to FIGS. 1 to 14.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a peripheral circuit structure;
a cell structure including gate electrodes and stacked on the peripheral circuit structure, the cell structure including a cell region, a connection region, and a peripheral circuit connection region;
a plurality of channel structures extending in a vertical direction through the gate electrodes in the cell region, each of the plurality of channel structures including a first end portion close to the peripheral circuit structure and a second end portion opposite to the first end portion; and
a common source layer connected to the second end portion of each of the channel structures in the cell region,
wherein the common source layer includes
a stack isolation trench extending in a first horizontal direction, and
a plurality of channel trenches extending in the first horizontal direction and spaced apart from each other with the stack isolation trench therebetween, in a second horizontal direction perpendicular to the first horizontal direction.

2. The semiconductor device of claim 1, wherein a width of each of the plurality of channel trenches in the second horizontal direction is less than a width of the stack isolation trench in the second horizontal direction.

3. The semiconductor device of claim 1, wherein the plurality of channel trenches and the stack isolation trench have widths in the second horizontal direction that decrease toward the peripheral circuit structure.

4. The semiconductor device of claim 1, further comprising:
a stack isolation insulating layer being through the gate electrodes in the vertical direction, the stack isolation insulating layer overlapping the stack isolation trench in the vertical direction.

5. The semiconductor device of claim 1, wherein the plurality of channel trenches overlap some of the plurality of channel structures in the vertical direction.

6. The semiconductor device of claim 1, wherein
each of the channel structures includes a cylindrical channel layer extending in the vertical direction, and
the cylindrical channel layer at the second end portion of each of the channel structures overlaps and contacts the common source layer in the vertical direction.

7. The semiconductor device of claim 1, wherein the cell structure further comprises:
an insulating wall extending in the vertical direction at a boundary between the cell region and the connection region; and
an insulating base layer in the connection region and the peripheral circuit connection region, being in contact with the insulating wall, and being at a same height as the insulating wall.

8. The semiconductor device of claim 1, wherein a width of each of the plurality of channel trenches in the second horizontal direction is same as a width of the stack isolation trench in the second horizontal direction.

9. The semiconductor device of claim 1, wherein the common source layer comprises polysilicon.

10. The semiconductor device of claim 1, further comprising:
a conductive laminate being in contact with a top surface of the common source layer, a sidewall of the conductive laminate being coplanar with a sidewall of the common source layer.

11. The semiconductor device of claim 10, further comprising:
an interlayer insulating layer filling the stack isolation trench and the plurality of channel trenches;
a rear pad on the interlayer insulating layer; and
a rear via passing through the interlayer insulating layer and connected to the rear pad and the conductive laminate.

12. The semiconductor device of claim 10, wherein the sidewall of the conductive laminate and the sidewall of the common source layer are inclined with respect to an axis parallel to the vertical direction.

13. A semiconductor device comprising:
a substrate;
a peripheral circuit structure on the substrate;
a cell structure including gate electrodes and stacked on the peripheral circuit structure, the cell structure including a cell region, a connection region, and a peripheral circuit connection region;
a plurality of channel structures extending in a vertical direction through the gate electrodes in the cell region, each of the plurality of channel structures including a first end portion close to the peripheral circuit structure and a second end portion opposite to the first end portion; and
a common source layer connected to the second end portion of each of the plurality of channel structures in the cell region,
wherein the common source layer includes
a stack isolation trench extending in a first horizontal direction, and
a plurality of channel trenches extending in the first horizontal direction and spaced apart from each other with the stack isolation trench therebetween, in a second horizontal direction perpendicular to the first horizontal direction, and wherein each of the plurality of channel structures includes
a cylindrical channel layer extending in the vertical direction, and
a charge storage layer and a blocking dielectric layer sequentially stacked on an outer wall of the cylindrical channel layer.

14. The semiconductor device of claim 13, wherein the charge storage layer includes a ferroelectric material.

15. The semiconductor device of claim 13, wherein the cylindrical channel layer includes polycrystalline silicon, doped silicon, SiGe, IGZO, Sn-IGZO, IWO, CuS₂, CuSe₂, WSe₂, IZO, ZTO, YZO, MoS₂, MoSe₂, WS₂, or a combination thereof.

16. The semiconductor device of claim 13, wherein
the common source layer is entirely arranged in the cell region, and
the plurality of channel trenches of the common source layer overlap some of the plurality of channel structures in the vertical direction.

17. The semiconductor device of claim 13, further comprising
a conductive laminate being in contact with a top surface of the common source layer,
wherein a sidewall of the conductive laminate is coplanar with a sidewall of the common source layer, and
the sidewall of the conductive laminate and the sidewall of the common source layer are away from a center in the second horizontal direction of each of the plurality of channel structures, toward the peripheral circuit structure.

18. The semiconductor device of claim 13, wherein each of the plurality of channel structures includes, in a cross-section perpendicular to a top surface of the substrate, an upper end portion having a trapezoidal cross-section in which a width thereof in the second horizontal direction increases toward the peripheral circuit structure.

19. A semiconductor device comprising:
a substrate;
a peripheral circuit structure on the substrate;
a cell structure including gate electrodes and stacked on the peripheral circuit structure, the cell structure including a cell region, a connection region, and a peripheral circuit connection region;
a plurality of channel structures extending in a vertical direction through the gate electrodes in the cell region, each of the plurality of channel structures including a first end portion close to the peripheral circuit structure and a second end portion opposite to the first end portion;
a common source layer connected to the second end portion of each of the plurality of channel structures in the cell region; and
a conductive laminate in contact with a top surface of the common source layer, a sidewall of the conductive laminate being coplanar with a sidewall of the common source layer,
wherein the common source layer includes
a stack isolation trench extending in a first horizontal direction, and
a plurality of channel trenches extending in the first horizontal direction, spaced apart from each other with the stack isolation trench therebetween in a second horizontal direction perpendicular to the first horizontal direction, each of the plurality of channel trenches having a narrower width in the second horizontal direction than the stack isolation trench, and
wherein each of the plurality of channel structures includes
a cylindrical channel layer extending in the vertical direction, and
a charge storage layer and a blocking dielectric layer sequentially stacked on an outer sidewall of the cylindrical channel layer, the charge storage layer including a ferroelectric material.

20. The semiconductor device of claim 19, further comprising:
an interlayer insulating layer filling the stack isolation trench and the plurality of channel trenches;
a rear pad on the interlayer insulating layer; and
a rear via passing through the interlayer insulating layer and connected to the rear pad and the conductive laminate.
